(19) United States
(12) Patent Application Publication
(10) Pub. No.: US 2026/0234440 A1
(43) Pub. Date: Aug. 13, 2026

(54) TUNGSTEN BUFFING COMPOSITION HAVING A NOVEL ANIONIC COLLOIDAL SILICA ABRASIVE

(71) Applicant: ENTEGRIS, INC., Billerica, MA (US)

(72) Inventors: Na Zhang, Naperville, IL (US); Steven Grumbine, Aurora, IL (US); Kim Long, Geneva, IL (US); William J. Ward, Aurora, IL (US); Galyna Arora, Naperville, IL (US)

(21) Appl. No.: 19/177,727

(22) Filed: Apr. 14, 2025

Related U.S. Application Data
(60) Provisional application No. 63/635,229, filed on Apr. 17, 2024.

(51) Int. Cl. C09G 1/02; B24B 37/04; C09K 3/14; H10P 52/40

(52) U.S. Cl. CPC C09G 1/02; B24B 37/044; C09K 3/1436; H10P 52/403

(57) ABSTRACT

A chemical mechanical polishing composition comprises, consists of, or consists essentially of a liquid carrier and anionic silica particles dispersed in the liquid carrier, wherein the anionic silica particles have an aspect ratio of less than about 1.3, a surface area in a range from about 40 m²/g to about 80 m²/g, and a zeta potential in a range from about −10 mV to about −40 mV in the polishing composition.

### FIELD OF THE INVENTION

The disclosed embodiments relate to chemical mechanical polishing compositions and more particularly to tungsten buff compositions having a novel anionic colloidal silica abrasive.

### BACKGROUND OF THE INVENTION

Chemical mechanical polishing (CMP) compositions and methods for polishing (or planarizing) the surface of a substrate are well known. Polishing compositions (also known as polishing slurries, CMP slurries, and CMP compositions) for polishing metal layers (such as tungsten) on a semiconductor substrate may include abrasive particles (e.g., including silica particles) dispersed in an aqueous carrier and various chemical additives such as an oxidizer (e.g., hydrogen peroxide), a rate accelerator (e.g., a catalyst), and a corrosion inhibitor.

Tungsten plug and interconnect processes are used to create the network of metal wires that connect the device transistors. In these processes tungsten layers are deposited in openings formed in a dielectric material and CMP is used to remove the excess metal from the dielectric and thereby form conductive plugs and/or interconnects. As transistor sizes continue to shrink, the use of conventional metal interconnect technology has become increasingly challenging. Multiple tungsten CMP steps are commonly required to achieve planarity metrics for advanced nodes, including a bulk polishing step to remove the majority of the tungsten metal and a buff polishing step to remove any remaining tungsten and barrier layers.

There are often numerous planarity (or topography) metrics that must be met, including array erosion, dishing, patterned oxide loss, edge-over erosion (EoE), and fanging over multiple array and line sizes. EoE refers to the erosion near the edge of an array (where the erosion is generally most severe), while fanging (also referred to as Iso Fang or Iso Line Fang) refers to the material loss in and around an isolated line. In some advanced devices EoE and fanging can be the most challenging topography metrics.

Despite many recent advances in CMP compositions, there remains a need for improved CMP compositions, particularly tungsten buff compositions that provide reduced edge over edge erosion and reduced fanging.

### BRIEF SUMMARY OF THE INVENTION

A chemical mechanical polishing composition is disclosed. The composition comprises, consists of, or consists essentially of a liquid carrier and anionic silica particles dispersed in the liquid carrier, wherein the anionic silica particles have an aspect ratio of less than about 1.3, a surface area in a range from about 40 m²/g to about 80 m²/g, and a zeta potential in a range from about −10 mV to about −40 mV in the polishing composition.

### DETAILED DESCRIPTION OF THE INVENTION

Chemical mechanical polishing compositions and methods are disclosed. In one example embodiment, a CMP composition includes a liquid carrier and anionic silica particles dispersed in the liquid carrier, wherein the anionic silica particles have an aspect ratio and a range from about 1 to about 1.3, a surface area in a range from about 40 m²/g to about 80 m²/g and a zeta potential in a range from about −10 mV to about −40 mV in the polishing composition. The polishing composition may have a pH of less than about 5 (e.g., in a range from about 2 to about 4). The polishing composition may further optionally include, for example, an iron containing polishing rate accelerator and a tungsten etch inhibitor.

While the disclosed embodiments are not strictly limited in this regard, the disclosed composition may be advantageously used to polish tungsten and/or molybdenum containing substrates and may be particularly well suited for tungsten and/or molybdenum buff polishing operations (which are sometimes referred to as second step CMP operations). In such embodiments, the composition may further optionally include an iron containing polishing accelerator and a corresponding stabilizer as described in more detail below as well as one or more tungsten and/or molybdenum etch inhibitors. The disclosed polishing compositions have been found to advantageously provide significantly improved topography control, particularly reduced fanging and EoE as compared to other compositions utilizing anionic particles.

The disclosed polishing compositions contain anionic abrasive particles suspended or dispersed in a liquid carrier. The liquid carrier is used to facilitate the application of the abrasive particles and various optional chemical additives to the surface of the substrate to be polished (e.g., planarized). The liquid carrier may include any suitable carrier (e.g., a solvent) including lower alcohols (e.g., methanol, ethanol, etc.), ethers (e.g., dioxane, tetrahydrofuran, etc.), water, and mixtures thereof. The liquid carrier preferably consists of, or consists essentially of, deionized water.

The disclosed polishing compositions include anionic colloidal silica particles. By “anionic” it is meant that the particles have a negative surface charge in the composition (e.g., at the pH of the composition). While not wishing to be bound to any particular theory, one aspect of the disclosed embodiments was the discovery that surface modified anionic colloidal silica particles having an aspect ratio of less than about 1.3, a surface area in a range from about 40 m²/g to about 80 m²/g, and a zeta potential in a range from about −10 mV to about −40 mV exhibit improved topography performance, particularly, improved (lower) EoE and Iso Fang.

The polishing composition comprises an abrasive that comprises, consists essentially of, or consists of surface-modified (e.g., surface-functionalized) colloidal silica particles. By surface modified it is meant that the colloidal silica particles have been surface-modified such that the modified colloidal silica particles have a negatively charged group on the surface of the particle such that the colloidal silica particles have a negative charge in the polishing composition. The negative charge is provided (at least in part) by the modification of the colloidal silica particles with the negatively charged group(s) (which is generally covalently attached to the silica surface).

As used herein, the term “negative charge” refers to a negative charge on the surface-modified colloidal silica particles in the polishing composition that is not readily reversible (i.e., irreversible or permanent), for example, via flushing, dilution, or filtration. A negative charge may be the result, for example, of covalently bonding an anionic species (e.g., a negatively-charged group) with the colloidal silica. In contrast, a reversible negative charge (a non-permanent negative charge) may be the result, for example, of an electrostatic interaction between an anionic species and the colloidal silica, such as anionic surfactant or anionic polymer which can, for example, electrostatically bind to the surface of a silica particle.

The negatively-charged group can be any suitable group that can affect a negative charge on the surface of the colloidal silica particles. For example, the negatively-charged group can be an organic acid (e.g., carboxylic acid, sulfonic acid, and/or phosphonic acid). In a preferred embodiment, the negatively-charged group comprises a sulfonate group, a carboxylate group, a phosphonate group, or combinations thereof.

In a preferred embodiment, the sulfonate group is a silane containing one or more sulfonate groups or sulfate groups. The sulfonate group also can be a sulfonate or sulfate precursor, which can subsequently be transformed into sulfonate or sulfate, for example, by oxidation. Suitable sulfonate groups include, for example, 3-(trihydroxysilyl)-1-propanesulfonic acid, triethoxysilylpropyl(polyethyleneoxy)propylsulfonic acid salts thereof such as potassium salts. Suitable sulfonate precursors include, for example, 3-mercaptopropyltrimethoxysilane, (mercaptomethyl)methyldiethoxysilane, and 3-mercaptopropyulmethyldimethoxysilane.

Suitable carboxylate groups or carboxylate precursors include, for example, (3-triethoxysilyl)propylsuccinic anhydride, carboxyethylsilane triol or salts thereof, and N-(trimethoxysilylpropyl)ethylenediaminetriacetic acid or salts thereof. A carboxylate precursor is converted (e.g., oxidation) to or converts in situ (e.g., during work-up) to a carboxylate group. Suitable phosphonate groups include, for example, 3-(trihydroxysilyl)propyl methylphosphonic acids and salts thereof.

The surface-modified colloidal silica particles can be prepared using any suitable method. Typically, the colloidal silica particles, prior to surface-modification with the negatively-charged group(s) (i.e., unmodified colloidal silica particles), are free or substantially free of negatively charged groups. The unmodified colloidal silica particles can be any suitable colloidal silica particles and may preferably be “wet-process” colloidal silica particles. As used herein, “wet-process” silica refers to a silica prepared by a precipitation, condensation-polymerization, or similar process (as opposed to, for example, fumed or pyrogenic silica). In a preferred embodiment, the colloidal silica particles are prepared by condensation-polymerization of Si(OH)₄. The precursor Si(OH)₄ can be obtained, for example, by hydrolysis of high purity alkoxysilanes such as tetramethylorthosilicate (TMOS). Such colloidal silica particles can be obtained as various commercially available products. In other embodiments, the silica particles may be prepared from silicates (e.g., sodium or potassium silicates).

The colloidal silica particles can be surface-modified using any suitable method. In an example embodiment, the surface treatment for providing a negatively-charged group to the surface of the colloidal silica particle is through silane surface reaction with the colloidal silica. For example, in the case of covalently attaching a sulfonic acid (e.g., a sulfonate group), which is an organic acid, to the colloidal silica, attachment can be carried out according to the method of Cano-Serrano et al., “Sulfonic acid-functionalized silica through quantitative oxidation of thiol groups”, Chem. Commun., 2003(2): 246-247 (2003). Specifically, the colloidal silica with sulfonic acids covalently attached to its surface is obtained by coupling silane coupling agents having a thiol group such as (3-mercaptopropyl)trimethoxysilane with the colloidal silica and then oxidizing the thiol group using a hydrogen peroxide water. Alternatively, for example, in the case of covalently attaching a carboxylic acid (i.e., a carboxylate group) to the colloidal silica, attachment can be carried out according to the method of Yamaguchi et al., “Novel silane coupling agents containing a photolabile 2-nitrobenzyl ester for introduction of a carboxy group”, Chemistry Letters, 3: 228-229 (2000). Specifically, the colloidal silica with a carboxylic acid covalently attached to its surface is obtained by coupling silane coupling agents containing photosensitive 2-nitrovinzyl ester with the colloidal silica and then irradiating it with light.

The anionic colloidal silica particles have a negative zeta potential in the polishing composition. As is known to those of ordinary skill in the art, the charge on dispersed particles, such as colloidal silica particles, is commonly referred to in the art as the zeta potential (or the electrokinetic potential). The zeta potential of a particle refers to the electrical potential difference between the electrical charge of the ions surrounding the particle and the electrical charge of the bulk solution of the polishing composition (e.g., the liquid carrier and any other components dissolved therein). The zeta potential may be obtained using commercially available instrumentation such as the Zetasizer® available from Malvern® Instruments, the ZetaPlus Zeta Potential Analyzer available from Brookhaven Instruments, and/or an electro-acoustic spectrometer available from Dispersion Technologies, Inc.

As also known to those of ordinary skill, the zeta potential may depend on the pH of the aqueous medium (e.g., aqueous carrier). For a given polishing composition, the isoelectric point of the particles is defined as the pH at which the zeta potential is zero. As the pH is increased or decreased away from the isoelectric point, the surface charge (and hence the zeta potential) may correspondingly decrease or increase (to negative or positive zeta potential values). Moreover, in the context of the present invention, the zeta potential is an indicator of the degree of surface-modification of the colloidal silica particles since a more negative zeta potential over a pH range of about 2 to about 5 generally corresponds to a higher degree of surface-modification.

The anionic colloidal silica particles may have a zeta potential in a range from about −10 mV to about −40 mV (e.g., from about −10 mV to about −35 mV, from about −10 mV to about −30 mV, from about −10 mV to about −25 mV, or from about −15 mV to about −25 mV) in the polishing composition. When the zeta potential is greater than about −10 mV (e.g., −5 mV) the colloidal silica particles tend to have reduced colloidal stability. When the zeta potential is less than about −40 mV (e.g., less than about −35 mV, less than about −30 mV, or less than about −25 mV), the EoE and/or Iso Fang performance may be degraded.

The anionic colloidal silica particles may be characterized as having a preferred combination of physical properties. In the disclosed embodiments, the anionic colloidal silica particles may be characterized as having a Brunauer-Emmett-Teller (BET) surface area in a range from about 40 m²/g to about 80 m²/g (e.g., in a range from about 40 m²/g to about 75 m²/g, from about 40 m²/g to about 70 m²/g, from about 40 m²/g to about 65 m²/g, from about 40 m²/g to about 60 m²/g, or from about 40 m²/g to about 55 m²/g). The BET surface area may be measured using a TriStar II Plus gas adsorption analyzer (Micromeritics Instrument Corporation, USA) according to the technique described in Colloids and Surfaces A: Physicochem. Eng. Aspects 322 (2008) 248-252.

It has been found that anionic colloidal silica particles having a BET surface area above or below the disclosed range (particularly above the range) exhibit more severe (worse) edge-over erosion and fanging performance. In other words, the edge-over erosion and fanging performance tends to be degraded when the surface area is outside the above disclosed range.

The anionic colloidal silica particles may be further characterized as having a number average aspect ratio less than about 1.3 (e.g., less than about 1.28, less than about 1.26, less than about 1.24, less than about 1.22, less than about 1.20, less than about 1.18, less than about 1.16, or less than about 1.15). It has been found that anionic colloidal silica particles having an aspect ratio greater than the above disclosed threshold exhibit more severe (worse) edge-over erosion and fanging performance. In other words, the edge-over erosion and fanging performance tend to be degraded when the aspect ratio is greater than the disclosed threshold.

The aspect ratio of a colloidal silica particle is defined herein as the maximum caliper diameter of the particle divided by the minimum caliper diameter of the particle (hence the aspect ratio is always greater than or equal to 1). The number average aspect ratio represents a statistical measure of the average (median) aspect ratio of the colloidal silica particles in the polishing composition (on a number rather than a weight basis). The number average aspect ratio may be referred to as AR50 since statistically half (50%) of the particles have an aspect ratio less than the median value and half (50%) of the particles have an aspect ratio greater than the median value.

The number average aspect ratio of the colloidal silica particles in a polishing composition may be determined by evaluating a large number of particles in high magnification transmission electron microscopy (TEM) images (e.g., at a magnification in a range from about 10,000 to about 30,000). To obtain a statistically significant median aspect ratio it is generally necessary to measure and compute the aspect ratio for a large number of colloidal silica particles (e.g., at least 500 or more particles or even 1000 or more particles) using a plurality of images (e.g., at least 10 or more images, 15 or more images, or even 20 or more images). The maximum caliper diameter and the minimum caliper diameter of each of the particles may be measured manually (particle by particle), for example, using the scale bar on the TEM image. However, a user-guided automated process is practically preferred based upon the requirement to evaluate a large number of particles. Such automated processes preferably make use of commercially available image analysis software. One suitable user guided automated process is described in significantly more detail below in Example 1.

The anionic colloidal silica particle may have substantially any suitable particle size as measured by the Zetasizer® (available from Malvern Instruments®). For example, the anionic colloidal silica particles may have an average particle size in a range from about 5 nm to about 300 nm (e.g., from about 10 nm to about 200 nm, from about 20 nm to about 200 nm, or from about 50 nm to about 150 nm). However, it has been found that preferred embodiments in which the anionic colloidal silica particles have an average particle size in a range from about 50 nm to about 100 nm (e.g., from about 60 nm to about 90 nm or from about 60 nm to about 80 nm) may exhibit the most favorable (the lowest values of) edge-over erosion and fanging performance provided that the anionic colloidal silica particles may also be characterized as having a zeta potential, a BET surface area, and an average aspect ratio in the above disclosed ranges.

The chemical-mechanical polishing composition may comprise any suitable amount of surface-modified colloidal silica particles at point of use. If the composition comprises too little surface-modified colloidal silica particles, the composition may not exhibit sufficient removal rate. In contrast, if the polishing composition comprises too much surface-modified colloidal silica particles, the composition may exhibit undesirable polishing performance, may not be cost effective, may be difficult to concentrate, and/or may lack stability.

Accordingly, the disclosed polishing composition may include about 0.1 wt. % or more (e.g., about 0.2 wt. % of more, about 0.5 wt. % or more, about 1 wt. % or more, about 1.5 wt. % or more, or about 2 wt. % or more) of the anionic colloidal silica particles at point of use. It will be appreciated that the composition preferably includes a low concentration of anionic particles at point of use to reduce costs (however the disclosed embodiments are not strictly limited in this regard). The polishing composition may include about 10 wt. % or less (e.g., about 5 wt. % or less, about 5 wt. % or less, about 3.5 wt. % or less, or about 3 wt. % or less) of the anionic colloidal silica particles at point of use. Therefore, the anionic colloidal silica particles may be present in the polishing composition in a concentration bounded by any two of the aforementioned endpoints. For example, the polishing composition may include from about 0.1 wt. % to about 10 wt. % (e.g., from about 0.5 wt. % to about 5 wt. %, about 1 wt. % to about 4 wt. %, or about 1 wt. % to about 3 wt. %) of the anionic colloidal silica particles at point of use.

The polishing composition is generally acidic having a pH of less than about 6. The polishing composition may have a pH of about 1 or more (e.g., about 1.5 or more or about 2 or more). Moreover, the polishing composition may have a pH of about 5 or less (e.g., about 4.5 or less, about 4 or less, about 3.5 or less, or about 3 or less). According, the polishing composition may have a pH in a range bounded by any two of the aforementioned endpoints, for example, in a range from about 1 to about 6 (e.g., from about 1.5 to about 5, from about 1.5 to about 4, from about 2 to about 3.5, or from about 2 to about 3).

The pH of the polishing composition may be achieved and/or maintained by any suitable means. The polishing composition may include substantially any suitable pH adjusting agents or buffering systems. For example, suitable pH adjusting agents may include nitric acid, sulfuric acid, phosphoric acid, phthalic acid, citric acid, adipic acid, oxalic acid, malonic acid, maleic acid, ammonium hydroxide, and the like while suitable buffering agents may include phosphates, sulfates, acetates, malonates, oxalates, borates, ammonium salts, and the like.

The disclosed polishing composition may include an iron-containing polishing rate accelerator (e.g., a tungsten or molybdenum rate accelerator). An iron-containing accelerator as used herein is an iron-containing chemical compound that may increase the removal rate of tungsten or molybdenum during a metal CMP operation. For example, the iron-containing accelerator may include a soluble iron-containing catalyst such as is disclosed in U.S. Pat. Nos. 5,958,288 and 5,980,775. Such an iron-containing catalyst may be soluble in the liquid carrier and may include, for example, ferric (iron III) or ferrous (iron II) compounds such as iron nitrate, iron sulfate, iron halides, including fluorides, chlorides, bromides, and iodides, as well as perchlorates, perbromates and periodates, and organic iron compounds such as iron acetates, carboxylic acids, acetylacetonates, citrates, gluconates, malonates, oxalates, phthalates, and succinates, and mixtures thereof.

An iron-containing accelerator may also include an iron-containing activator (e.g., a free radical producing compound) or an iron-containing catalyst associated with (e.g., coated or bonded to) the surface of the colloidal silica particle such as is disclosed in U.S. Pat. Nos. 7,029,508 and 7,077,880. For example, the iron-containing accelerator may be bonded with the silanol groups on the surface of the colloidal surface particles.

The amount of iron-containing accelerator in the polishing composition may be varied depending upon the oxidizing agent used and the chemical form of the accelerator. When the oxidizing agent is hydrogen peroxide (or one of its analogs) and a soluble iron-containing catalyst is used (such as ferric nitrate or hydrates of ferric nitrate), the catalyst may be present in the composition at point of use in an amount sufficient to provide a range from about 0.5 to about 3000 ppm Fe based on the total weight of the composition. For example, polishing compositions configured for bulk tungsten or molybdenum removal may include about 1 ppm Fe or more at point of use (e.g., about 5 ppm or more, about 10 ppm or more, or about 15 ppm or more). The polishing composition may include about 500 ppm Fe or less at point of use (e.g., about 200 ppm or less, about 100 ppm or less, or about 50 ppm or less). Accordingly, the point of use polishing composition may include Fe in a range bounded by any one of the above endpoints (e.g., from about 1 ppm to about 500 ppm, from about 5 ppm to about 200 ppm, from about 10 ppm to about 100 ppm, or from about 15 ppm to about 50 ppm). For tungsten or molybdenum buff applications that do not require high metal removal rates, the catalyst may be present in lower amounts, for example, from about 0.1 ppm to about 50 ppm Fe (e.g., from about 0.2 ppm to about 20 ppm or from about 0.2 to about 10 ppm) at point of use.

Embodiments of the polishing composition including an iron-containing accelerator may further include a stabilizer. Without such a stabilizer, the iron-containing accelerator and the oxidizing agent, if present, may react in a manner that degrades the oxidizing agent rapidly over time. The addition of a stabilizer tends to reduce the effectiveness of the iron-containing accelerator such that the choice of the type and amount of stabilizer added to the polishing composition may have a significant impact on CMP performance. The addition of a stabilizer may lead to the formation of a stabilizer/accelerator complex that inhibits the accelerator from reacting with the oxidizing agent, if present, while at the same time allowing the accelerator to remain sufficiently active so as to promote rapid tungsten or molybdenum polishing rates.

Useful stabilizers include phosphoric acid, organic acids such as dicarboxylic acids, phosphonate compounds, nitriles, and other ligands which bind to the metal and reduce its reactivity toward hydrogen peroxide decomposition and mixture thereof. The acid stabilizers may be used in their conjugate form, e.g., the carboxylate can be used instead of the carboxylic acid. The term “acid” as it is used herein to describe useful stabilizers also means the conjugate base of the acid stabilizer. Stabilizers can be used alone or in combination and significantly reduce the rate at which oxidizing agents such as hydrogen peroxide decompose.

Preferred stabilizers include phosphoric acid, acetic acid, phthalic acid, citric acid, adipic acid, oxalic acid, malonic acid, aspartic acid, succinic acid, glutaric acid, pimelic acid, suberic acid, azelaic acid, sebacic acid, maleic acid, glutaconic acid, muconic acid, ethylenediaminetetraacetic acid (EDTA), propylenediaminetetraacetic acid (PDTA), and mixtures thereof. The preferred stabilizers may be added to the compositions of this invention in an amount ranging from about 1 equivalent per iron-containing accelerator to about 3.0 weight percent or more (e.g., from about 1 equivalent to about 5 equivalents, or from about 3 equivalents to about 10 equivalents). As used herein, the term “equivalent per iron-containing accelerator” means one molecule of stabilizer per iron ion in the composition. For example, two equivalents per iron-containing accelerator means two molecules of stabilizer for each catalyst ion.

The polishing composition may optionally further include an oxidizing agent. The oxidizing agent may be added to the polishing composition during the slurry manufacturing process or just prior to the CMP operation (e.g., in a tank located at the semiconductor fabrication facility). Preferred oxidizing agents include inorganic or organic per-compounds. A per-compound as defined herein is a compound containing at least one peroxy group (—O—) or a compound containing an element in its highest oxidation state. Examples of compounds containing at least one peroxy group include but are not limited to hydrogen peroxide and its adducts such as urea hydrogen peroxide and percarbonates, organic peroxides such as benzoyl peroxide, peracetic acid, and di-t-butyl peroxide, monopersulfates (SO₅^{═}), dipersulfates (S₂O₈^{═}), and sodium peroxide. Examples of compounds containing an element in its highest oxidation state include but are not limited to periodic acid, periodate salts, perbromic acid, perbromate salts, perchloric acid, perchlorate salts, perboric acid, and perborate salts and permanganates. The most preferred oxidizing agent is hydrogen peroxide.

The oxidizing agent may be present in the polishing composition in substantially any suitable amount, for example, from about 0.0 wt. % to about 20 wt. % at point of use. In example embodiments configured for bulk tungsten or molybdenum removal that include a hydrogen peroxide oxidizer and a soluble iron-containing catalyst, the oxidizer may be present in the polishing composition in an amount ranging from about 0.1 wt. % to about 10 wt. % at point of use (e.g., from about 0.5 wt. % to about 5 wt. % or from about 1 wt. % to about 4 wt. %). In example embodiments configured for buff tungsten or molybdenum applications, the amount of hydrogen peroxide in the composition is generally less, for example, from about 0 wt. % to about 2 wt. % (or even from about 0 wt. % to about 1 wt. %).

The disclosed polishing composition may further optionally include a compound that inhibits (or further inhibits) metal etching (e.g., tungsten or molybdenum etching/corrosion). Suitable inhibitor compounds are intended to inhibit the conversion of solid metal into soluble metal compounds while at the same time allowing for effective removal of solid metal via the CMP operation. The polishing composition may include substantially any suitable inhibitor, for example, inhibitor compounds disclosed in commonly assigned U.S. Pat. Nos. 9,238,754; 9,303,188; and 9,303,189.

Example classes of compounds that that are useful inhibitors of metal (e.g., tungsten) etching include compounds having nitrogen containing functional groups such as nitrogen containing heterocycles, alkyl ammonium ions, amino alkyls, and amino acids. Useful amino alkyl corrosion inhibitors include, for example, hexylamine, tetramethyl-p-phenylene diamine, octylamine, diethylene triamine, dibutyl benzylamine, aminopropylsilanol, aminopropylsiloxane, dodecylamine, mixtures thereof, and synthetic and naturally occurring amino acids including, for example, lysine, tyrosine, histidine, glutamine, glutamic acid, cystine, and glycine (aminoacetic acid).

The inhibitor compound may alternatively and/or additionally include an amine compound in solution in the liquid carrier. The amine compound (or compounds) may include a primary amine, a secondary amine, a tertiary amine, or a quaternary amine. The amine compound may further include a monoamine, a diamine, a triamine, a tetramine, or an amine based polymer having a large number of repeating amine groups (e.g., 4 or more amine groups).

The disclosed polishing compositions may include substantially any suitable concentration of the tungsten etch inhibitor compound. In general, the concentration is desirably high enough to provide adequate etch inhibition at a range of oxidizer (e.g., hydrogen peroxide) concentrations, but low enough so that the compound is soluble and does not reduce tungsten polishing rates below acceptable levels. By soluble it is meant that the compound is fully dissolved in the liquid carrier or that it forms micelles in the liquid carrier or is carried in micelles. In certain embodiments the concentration of inhibitor may be in a range from about 0 ppm by weight to about 10,000 ppm by weight at point of use (e.g., from about 0 ppm by weight to about 5000 ppm by weight or from about 0 ppm by weight to about 1000 ppm by weight).

The disclosed polishing composition may further optionally include a cationic polymer and an anionic polymer or an anionic surfactant. In embodiments including a cationic polymer and an anionic polymer, the polymers may form a polyelectrolyte complex (although the disclosed embodiments are expressly not limited in this regard). While not wishing to be bound by theory, it is believed that a polyelectrolyte complex may provide improved colloidal stability of the anionic abrasive particles via providing stearic spacing that inhibits anionic particle agglomeration via interaction with the cationic polymer.

Notwithstanding the foregoing, an optional cationic polymer may include substantially any suitable cationic polymer, for example, a cationic homopolymer, a cationic copolymer including at least one cationic monomer (and an optional nonionic monomer), and combinations thereof. The cationic polymer may be advantageously selected, for example, to improve planarization efficiency or the final topography (e.g., as measured via line dishing and array erosion) of the polished wafer.

The cationic polymer may be substantially any suitable cationic homopolymer including cationic monomer repeat units, for example, including quaternary amine groups as repeat units. The quaternized amine groups may be acyclic or incorporated into a ring structure. Quaternized amine groups include tetrasubstituted nitrogen atoms substituted with four groups independently selected from alkyl, alkenyl, aryl, arylalkyl, acrylamido, or methacrylate groups. When included into a ring structure, quaternized amine groups include either a heterocyclic saturated ring including a nitrogen atom and are further substituted with two groups as described above or a heteroaryl group (e.g., imidazole or pyridine) having a further group as described above bonded to the nitrogen atom. Quaternized amine groups possess a positive charge (i.e., are cations having associated anionic moieties, thereby forming salts). It is also suitable for the cationic polymer to be further modified by alkylation, acylation, ethoxylation, or other chemical reaction, in order to alter the solubility, viscosity, or other physical parameter of the cationic polymer. Suitable quaternary amine monomers include, for example, quaternized vinylimidazole (vinylimidazolium), methacryloyloxyethyltrimethylammonium (MADQUAT), diallyldimethylammonium (DADMA), methacrylamidopropyl trimethylammonium (MAPTA), quaternized dimethylaminoethyl methacrylate (DMAEMA), epichlorohydrin-dimethylamine (epi-DMA), quaternized poly(vinyl alcohol) (PVOH), quaternized hydroxyethylcellulose, and combinations thereof. It will be appreciated that MADQUAT, DADMA, MAPTA, and DMAEMA commonly include a counter anion such as a carboxylate (e.g., acetate) or a halide anion (e.g., chloride). The disclosed embodiments are not limited in this regard.

The cationic polymer may also be a copolymer including at least one cationic monomer (e.g., as described in the preceding paragraph) and at least one nonionic monomer. Non-limiting examples of suitable nonionic monomers include vinylpyrrolidone, vinylcaprolactam, vinylimidazole, acrylamide, vinyl alcohol, polyvinyl formal, polyvinyl butyral, poly(vinyl phenyl ketone), vinylpyridine, polyacrolein, cellulose, hydroxylethyl cellulose, ethylene, propylene, styrene, and combinations thereof.

Example cationic polymers include but are not limited to poly(vinylimidazolium), polyethyleneimine, poly(methacryloyloxyethyltrimethylammonium) (polyMADQUAT), poly(diallyldimethylammonium) (e.g., polyDADMAC) (i.e., Polyquaternium-6), poly(dimethylamine-co-epichlorohydrin), poly[bis(2-chloroethyl) ether-alt-1,3-bis[3-(dimethylamino)propyl]urea](i.e., Polyquaternium-2), copolymers of hydroxyethyl cellulose and diallyldimethylammonium (i.e., Polyquaternium-4), copolymers of acrylamide and diallyldimethylammonium (i.e., Polyquaternium-7), quaternized hydroxyethylcellulose ethoxylate (i.e., Polyquaternium-10), copolymers of vinylpyrrolidone and quaternized dimethylaminoethyl methacrylate (i.e., Polyquatemium-11), copolymers of vinylpyrrolidone and quaternized vinylimidazole (i.e., Polyquatemium-16), Polyquaternium-24, a terpolymer of vinylcaprolactam, vinylpyrrolidone, and quaternized vinylimidazole (i.e., Polyquaternium-46), 3-Methyl-1-vinylimidazolium methyl sulfate-N-vinylpyrrolidone copolymer (i.e., Polyquaternium-44), and copolymers of vinylpyrrolidone and diallyldimethylammonium. Additionally, suitable cationic polymers include cationic polymers for personal care such as Luviquat® Supreme, Luviquat® Hold, Luviquat® UltraCare, Luviquat® FC 370, Luviquat® FC 550, Luviquat® FC 552, Luviquat® Excellence, GOHSEFIMER K210™, GOHSENX K-434, and combinations thereof. In certain example embodiments, poly(diallyldimethylammonium) (e.g., polyDADMAC) is a preferred cationic polymer.

In certain embodiments, the cationic polymer may include a repeating amino acid monomer (such compounds may also be referred to as polyamino acid compounds). Suitable polyamino acid compounds may include substantially any suitable amino acid monomer groups, for example, including polyarginine, polyhistidine, polyalanine, polyglycine, polytyrosine, polyproline, polyornithine and polylysine. In certain example embodiments, polylysine is a preferred polyamino acid and a preferred cationic polymer. It will be understood that polylysine may include F-polylysine and/or α-polylysine composed of D-lysine and/or L-lysine. The polylysine may thus include ε-poly-L-lysine, α-poly-D-lysine, F-poly-L-lysine, F-poly-D-lysine, and mixtures thereof. In certain embodiments, the polylysine may be primarily F-poly-L-lysine. It will further be understood that the polyamino acid compound (or compounds) may be used in any accessible form, e.g., the conjugate acid or base and salt forms of the polyamino acid may be used instead of (or in addition to) the polyamino acid.

The cationic polymer may also (or alternatively) include a derivatized polyamino acid (i.e., a cationic polymer containing a derivatized amino acid monomer unit). For example, the derivatized polyamino acid may include derivatized polyarginine, derivatized polyornithine, derivatized polyhistidine, and derivatized polylysine. CMP compositions including derivatized polyamino acid compounds are disclosed in U.S. Provisional Patent Application Ser. No. 62/958,033, which is incorporated by reference herein in its entirety.

The polishing composition may include substantially any suitable amount of the cationic polymer at point of use. For example, the polishing composition may include 0.1 ppm by weight or more cationic polymer at point of use (e.g., about 0.2 ppm by weight or more, about 0.3 ppm by weight or more, about 0.5 ppm by weight or more, about 1 ppm by weight or more, 2 ppm by weight or more, 5 ppm by weight or more, 10 ppm by weight or more, 20 ppm by weight or more, or about 30 ppm by weight or more). The amount of cationic polymer in the composition may be 200 ppm by weight or less at point of use (e.g., about 100 ppm by weight or less, about 75 ppm by weight or less, about 50 ppm by weight or less, or about 25 ppm by weight or less). Accordingly, it will be understood that the amount of cationic polymer may be in a range bounded by any two of the aforementioned endpoints, for example, in a range from about 0.1 ppm by weight to about 200 ppm by weight at point of use (e.g., from about 1 ppm by weight to about 200 ppm by weight, from about 2 ppm by weight to about 50 ppm by weight, or from about 20 ppm by weight to about 200 ppm by weight) depending on the particular cationic polymer used.

A corresponding anionic compound may include substantially any suitable anionic polymer and/or substantially any suitable anionic surfactant. An anionic polymer may have a negatively charged monomer or repeating negatively charged group and may include, for example, an anionic homopolymer, an anionic copolymer including at least one anionic monomer (and an optional nonionic monomer), and combinations thereof.

For example suitable anionic polymers may include poly(acrylic acid) (PAA), poly(methacrylic acid) (PMAA), poly(maleic acid) (PMA), poly(vinyl sulfonic acid) (PVSA), poly(styrene sulfonic acid) (PSSA), poly(2-acrylamido-2-methylpropane sulfonic acid), poly(styrenesulfonic acid-co-maleic acid), poly(acrylic acid)-co-poly (2-acrylamido 2-methylpropane sulfonic acid) and mixtures thereof. It will be appreciated that the use of PAA, PMAA, and PMA may not always be suitable for use in compositions including certain of the iron containing accelerators described below.

In certain advantageous embodiments, the anionic polymer may include a polysulfonic acid polymer comprising sulfonic acid monomer units. Example polysulfonic acid polymers include PVSA, PSSA, poly(2-acrylamido-2-methylpropane sulfonic acid), poly(styrenesulfonic acid-co-maleic acid), and mixtures thereof. PVSA and PSSA are most preferred.

An anionic surfactant may include a long carbon chain alky sulfonate, for example, including 10 or more carbon atoms. Suitable anionic surfactants include anionic surfactants having a functional group that carries a negative charge in a desired pH working space (e.g. sulfonate and sulfate), and an alkyl group. Preferred anionic surfactants may have the negatively charged functional group accompanied by ether and/or phenol. The negatively charged functional group is preferably a sulfate group or a sulfonate group. Example suitable anionic surfactants include disodium hexadecyldiphenyloxide disulfonate, ammonium polyoxyethylene styrenated aryl sulfate, and ammonium alkyl polyoxethylene ether sulfate (such as ammonium polyoxyethylene oleyl cetyl ether sulfate, and ammonium lauryl polyoxyethylene ether sulfate).

It will of course be understood that where applicable the above described anionic polymers and anionic surfactants may be provided as the parent acids, or as conjugate base salts or mixtures thereof, including any reasonable positively charged counterions, such as sodium, potassium, or ammonium cations.

The polishing composition may include substantially any suitable amount of the anionic polymer or anionic surfactant at point of use. For example, the polishing composition may include 0.5 ppm by weight or more anionic polymer or anionic surfactant at point of use (e.g., about 1 ppm by weight or more, about 2 ppm by weight or more, about 5 ppm by weight or more, or about 10 ppm by weight or more). The amount of anionic polymer or anionic surfactant in the composition may be 2,000 ppm by weight or less at point of use (e.g., about 1000 ppm by weight or less, about 500 ppm by weight or less, about 200 ppm by weight or less, or about 100 ppm by weight or less). Accordingly, it will be understood that the amount of anionic polymer or anionic surfactant may be in a range bounded by any two of the aforementioned endpoints, for example, in a range from about 0.5 ppm by weight to about 2,000 ppm by weight at point of use (e.g., from about 1 ppm by weight to about 1000 ppm by weight, from about 5 ppm by weight to about 200 ppm by weight, or from about 10 ppm by weight to about 100 ppm by weight).

In example embodiments the anionic polymer may include a polysulfonic acid polymer and the cationic polymer may include a polyamino acid or a repeating monomer having a quaternary amine group. In one particularly preferred embodiment the anionic polymer includes polystyrenesulfonic acid (PSSA) and the cationic polymer comprises polylysine (e.g., F-poly-L-lysine).

The anionic and cationic polymers may have substantially any suitable molecular weights and need not have the same molecular weight or even similar molecular weights. For example, the anionic and cationic polymers may have an average molecular weight of about 200 g/mol or more (e.g., about 1,000 g/mol or more, about 3,000 g/mol or more, or about 10,000 g/mol or more). The anionic and cationic polymers may have an average molecular weight of about 5,000,000 g/mol or less (e.g., about 1,000,000 g/mol or less, about 300,000 or about 100,000 g/mol or less). Accordingly, it will be understood that the anionic and cationic polymers may have an average molecular weight bounded by any two of the aforementioned endpoints. For example, the cationic polymer may have an average molecular weight from about 200 g/mol to about 5,000,000 g/mol (e.g., from about 1,000 g/mol to about 1,000,000 g/mol or from about 3,000 g/mol to about 300,000 g/mol).

Disclosed polishing compositions may include substantially any additional optional chemical additives. For example, the disclosed compositions may include still further etch inhibitors, dispersants, and biocides. Such additional additives are purely optional. The disclosed embodiments are not so limited and do not require the use of any one or more of such additives. In embodiments further including a biocide, the biocide may include any suitable biocide, for example an isothiazolinone biocide known to those of ordinary skill in the art.

The polishing composition may be prepared using any suitable techniques, many of which are known to those skilled in the art. The polishing composition may be prepared in a batch or continuous process. Generally, the polishing composition may be prepared by combining the components thereof in any order. The term “component” as used herein includes the individual ingredients (e.g., the colloidal silica, the iron-containing accelerator, the amine compound, etc.).

For example, the polishing composition components (such as the iron-containing accelerator, the stabilizer, the tungsten etch inhibitor, and/or the biocide) may be added directly to a silica dispersion (including the disclosed anionic colloidal silica). The silica dispersion and the other components may be blended together using any suitable techniques for achieving adequate mixing. Such blending/mixing techniques are well known to those of ordinary skill in the art. The oxidizing agent, when present, may be added at any time during the preparation of the polishing composition. For example, the polishing composition may be prepared prior to use, with one or more components, such as the oxidizing agent, being added just prior to the CMP operation (e.g., within about 1 minute, or within about 10 minutes, or within about 1 hour, or within about 1 day, or within about 1 week of the CMP operation). The polishing composition also may also be prepared by mixing the components at the surface of the substrate (e.g., on the polishing pad) during the CMP operation.

The polishing composition may advantageously be supplied as a one-package system comprising a colloidal silica having the above-described physical properties and other optional components. An oxidizing agent may be desirably supplied separately from the other components of the polishing composition and may be combined, e.g., by the end-user, with the other components of the polishing composition shortly before use (e.g., 1 week or less prior to use, 1 day or less prior to use, 1 hour or less prior to use, 10 minutes or less prior to use, or 1 minute or less prior to use). Various other two-container, or three- or more-container, combinations of the components of the polishing composition are within the knowledge of one of ordinary skill in the art.

The polishing composition of the invention may also be provided as a concentrate which is intended to be diluted with an appropriate amount of water prior to use. In such an embodiment, the polishing composition concentrate may include the abrasive (e.g., silica), the iron-containing accelerator, the stabilizer, the tungsten etch inhibitor, and an optional biocide in amounts such that, upon dilution of the concentrate with an appropriate amount of water, and an optional oxidizing agent if not already present in an appropriate amount, each component of the polishing composition will be present in the polishing composition in an amount within the appropriate ranges recited above for each component. For example, the colloidal silica and other optional components may each be present in the polishing composition in an amount that is about 2 times (e.g., about 3 times, about 4 times, about 5 times, or even about 10 times) greater than the point of use concentrations recited above for each component so that, when the concentrate is diluted with an equal volume of (e.g., 2 equal volumes of water, 3 equal volumes of water, 4 equal volumes of water, or even 9 equal volumes of water respectively), along with the oxidizing agent in a suitable amount, each component will be present in the polishing composition in an amount within the ranges set forth above for each component. Furthermore, as will be understood by those of ordinary skill in the art, the concentrate may contain an appropriate fraction of the water present in the final polishing composition in order to ensure that other components are at least partially or fully dissolved in the concentrate.

The disclosed polishing compositions may be advantageously used to polish a substrate including a tungsten layer or a molybdenum layer and a dielectric material such as silicon oxide. In such applications, the tungsten or molybdenum layer may be deposited over one or more barrier layers, for example, including titanium and/or titanium nitride (TiN). The dielectric layer may be a metal oxide such as a silicon oxide layer derived from tetraethylorthosilicate (TEOS), porous metal oxide, porous or non-porous carbon doped silicon oxide, fluorine-doped silicon oxide, glass, organic polymer, fluorinated organic polymer, or any other suitable high or low-k insulating layer.

The polishing method of the invention is particularly suited for use in conjunction with a chemical mechanical polishing (CMP) apparatus. Typically, the apparatus includes a platen, which, when in use, is in motion and has a velocity that results from orbital, linear, or circular motion, a polishing pad in contact with the platen and moving with the platen when in motion, and a carrier that holds a substrate to be polished by contacting and moving relative to the surface of the polishing pad. The polishing of the substrate takes place by the substrate being placed in contact with the polishing pad and the polishing composition of the invention and then the polishing pad moving relative to the substrate, so as to abrade at least a portion of the substrate (such as tungsten, titanium, titanium nitride, and/or a dielectric material as described herein) to polish the substrate.

A substrate may be planarized or polished with the chemical mechanical polishing composition with any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof.

It will be understood that the disclosure includes numerous embodiments. These embodiments include but are not limited to the embodiment listed in the claims.

The following examples further illustrate the invention but, of course, should not be construed as in any way limiting its scope.

### Example 1

Ten anionic colloidal silica containing polishing compositions were prepared and evaluated. The colloidal silica particles were selected to have a range of particle sizes, surface areas, and aspect ratios. The colloidal silicas were treated with an anionic compound to impart a permanent negative charge prior to formulating the polishing compositions as described in Chem. Commun. 2003(2): 246-247(2003). Specifically, the colloidal silica with sulfonic acids covalently attached to its surface may be obtained by coupling silane coupling agents having a thiol group such as (3-mercaptopropyl)trimethoxysilane with the colloidal silica and then oxidizing the thiol group using hydrogen peroxide. The silicas were modified to the level of desired zeta potential as indicated in Table 1.

Each of the polishing compositions included 3.5 weight percent of the treated anionic colloidal silica particles (prepared as described above). The polishing compositions further included 670 ppm by weight malonic acid, 300 ppm by weight ferric nitrate nonahydrate (Fe(NO₃)₃·9H₂O), 2500 ppm by weight glycine, 8 ppm by weight Kathon LX preservative, and 2 weight percent hydrogen peroxide. The pH of each composition was adjusted to 2.45 using nitric acid or potassium hydroxide.

Samples of each of the colloidal silica compositions were prepared for TEM imaging (prior to adding the hydrogen peroxide) by drop-casting 30 μL samples onto lacey carbon-coated Cu grids deployed on filters to wick away excess liquid. After drying, multiple TEM bright field images were obtained of the remaining particles (the particles that remain after wicking away of the liquid). In this example, 20 images were obtained for each sample and were stacked into a single file using FIJI open-source image processing software (https://en.wikipedia.org/wiki/Fiji_(software). Each image was obtained at a magnification of 20,000 and included 2048×2048 pixels. Using the FIJI software, the background was subtracted (using a rolling ball process) and the images were contrast enhanced to scale the intensity resolution. The pixel size was computed and input into the software (using the image scale bar). Machine learning software (using the trainable WEKA segmentation algorithm available in FIJI) was used to create binary images of the particle and background (a black particle in a white background). The machine learning software was user guided with the user defining selected particles. The WEKA software then evaluated selected images in the stack. An iterative process enabled the software to accurately find the particles. The learned algorithm was then applied to whole stack to generate binary images. A particle analyzing routine (available in FIJI) was then applied to the images in the stack to compute an aspect ratio for each identified particle in each image (the aspect ratio being defined as the maximum caliper diameter of the particle divided by the minimum caliper diameter of the particle). The median value (AR50) was computed and is recorded in Table 1 for each of the colloidal silica compositions.

The average particle size and the zeta potential of the anionic colloidal silica particles in each of the polishing compositions was measured using a Zetasizer® available from Malvern Instruments prior to adding hydrogen peroxide to the compositions. The BET surface area of each particle was measured as described above using a TriStar II Plus gas adsorption analyser according to Colloids and Surfaces A: Physicochem. Eng. Aspects 322 (2008) 248-252. The results of the particle characterization measurements are also recorded in Table 1.

TABLE 1

| | | | | Zeta |
|---|---|---|---|---|
| Polishing | TEM AR | DLS Particle | BET SA | Potential |
| Composition | (AR50) | Size (nm) | (m²/g) | (mV) |
| 1A (comparative) | 1.38 | 78 | 90 | −10 |
| 1B (comparative) | 1.38 | 82 | 90 | −16 |
| 1C (comparative) | 1.29 | 71 | 91 | −37 |
| 1D (comparative) | 1.19 | 102 | 47 | −45 |
| 1E (comparative) | 1.22 | 140 | 41 | −7 |
| 1F (comparative) | 1.1 | 122 | 36 | −18 |
| 1G (inventive) | 1.2 | 82 | 60 | −14 |
| 1H (inventive) | 1.1 | 79 | 44 | −24 |
| 1I (inventive) | 1.1 | 62 | 55 | −14 |
| 1J (inventive) | 1.09 | 75 | 54 | −18 |

As is readily apparent from the results set forth in Table 1, each of the inventive polishing compositions has an anionic colloidal silica having a zeta potential in a range from about −10 mV to about −40 mV (e.g., from about −10 mV to about −25 mV) in the polishing composition, an aspect ratio of less than about 1.3 (e.g., less than or equal to about 1.2) and a surface area in a range from about 40 m²/g to about 80 m²/g (e.g., from about 40 m²/g to about 60 m²/g). The inventive polishing compositions disclosed in this example also have a particle size in a range from about 50 nm to about 100 nm (e.g., from about 60 nm to about 90 nm).

### Example 2

The blanket wafer and patterned wafer polishing performance of each of the ten polishing compositions prepared in Example 1 was evaluated. The wafers were polished using a Mirra® CMP polishing tool (Applied Materials) with an E6088 polishing pad (Entegris) and ex-situ conditioning using a Saesol C1 conditioner at 9 lbs for 12 seconds. Tungsten, TEOS, and SiN polishing rates were obtained by polishing 200 mm blanket tungsten, TEOS, and PE-SiN and LP-SiN wafers for 60 seconds at a downforce of 3 psi, a platen speed of 100 rpm, a head speed of 85 rpm, and a slurry flow rate was 120 mL/min. Patterned wafers having a 2 kÅ tungsten film (MIT 854) were polished at the same conditions until endpoint with a 15 percent overpolish. Blanket wafer polishing rates are shown in Table 2A. Patterned wafer removal rates and oxide loss are shown in Table 2B. Erosion, EoE, and fanging are shown in Table 2C. In Table 2C, the array erosion refers to the average erosion for the array, the Total EoE refers to the total erosion at the edge of the array, and the Local EoE is the excess erosion at the edge of the array (i.e., Total EoE minus Array Erosion).

TABLE 2A

| Polishing | W RR | TEOS RR | LP SiN RR | PE SiN RR |
|---|---|---|---|---|
| Composition | (Å/min) | (Å/min) | (Å/min) | (Å/min) |
| 1A (comparative) | 2968 | 546 | 794 | 1268 |
| 1B (comparative) | 2708 | 373 | 808 | 1286 |
| 1C (comparative) | 2441 | 397 | 616 | 963 |
| 1D (comparative) | 1860 | 280 | 252 | 371 |
| 1E (comparative) | 2055 | 451 | 431 | 606 |
| 1F (comparative) | 1315 | 242 | 129 | 215 |
| 1G (inventive) | 1859 | 275 | 498 | 796 |
| 1H (inventive) | 1522 | 357 | 217 | 399 |
| 1I (inventive) | 1361 | 342 | 303 | 580 |
| 1J (inventive) | 1463 | 315 | 317 | 532 |

TABLE 2B

| Polishing | Pattern W | Pattern Oxide | Pattern Oxide |
|---|---|---|---|
| Composition | RR (Å/min) | RR (Å/min) | Loss (Å) |
| 1A (comparative) | 3539 | 1748 | 437 |
| 1B (comparative) | 3134 | 1470 | 367 |
| 1C (comparative) | 3063 | 1324 | 331 |
| 1D (comparative) | 2931 | 1005 | 251 |
| 1E (comparative) | 3336 | 1205 | 301 |
| 1F (comparative) | 2934 | 817 | 204 |
| 1G (inventive) | 2933 | 833 | 208 |
| 1H (inventive) | 2804 | 829 | 207 |
| 1I (inventive) | 2638 | 882 | 220 |
| 1J (inventive) | 2642 | 830 | 207 |

TABLE 2C

| Polishing | Fanging | Array Erosion | Total EoE | Local EoE |
|---|---|---|---|---|
| Composition | 1 × 1 μm (Å) | 0.18 × 0.18 (Å) | (Å) | (Å) |
| 1A (comparative) | 582 | 474 | 614 | 140 |
| 1B (comparative) | 572 | 443 | 598 | 155 |
| 1C (comparative) | 393 | 265 | 415 | 150 |
| 1D (comparative) | 170 | 146 | 242 | 96 |
| 1E (comparative) | 182 | 472 | 472 | 0 |
| 1F (comparative) | 50 | 69 | 107 | 38 |
| 1G (inventive) | 77 | 180 | 180 | 0 |
| 1H (inventive) | 30 | 36 | 48 | 12 |
| 1I (inventive) | 51 | 64 | 104 | 30 |
| 1J (inventive) | 20 | 28 | 61 | 33 |

As is evident from the results set forth Tables 2A-2C, inventive polishing compositions 1G, 1H, 1I, and 1J (and particularly compositions 1H and 1J) exhibit significantly improved fanging, erosion, and EoE as compared to the comparative compositions. Moreover, the inventive polishing compositions 1G, 1H, 1I, and 1J exhibit a similar patterned tungsten removal rate and superior patterned oxide loss and removal rate as compared to the other compositions. It is also evident that the inventive compositions exhibit lower blanket tungsten removal rates, indicating that the inventive compositions may be best suited for tungsten buff applications.

### Example 3

Three anionic colloidal silica containing polishing compositions were prepared and evaluated. The colloidal silica particles were selected to have a range of particle sizes, surface areas, and aspect ratios. The colloidal silicas were treated with an anionic compound to impart a permanent negative charge prior to formulating the polishing compositions as described in Chem. Commun., 2003(2): 246-247(2003). Specifically, the colloidal silica with sulfonic acids covalently attached to its surface may be obtained by coupling silane coupling agents having a thiol group such as (3-mercaptopropyl)trimethoxysilane with the colloidal silica and then oxidizing the thiol group using hydrogen peroxide. The silicas were modified to the level of desired zeta potential as indicated in Table 3.

Each of the polishing compositions included 0.5 weight percent of the treated anionic colloidal silica particles (prepared as described above). The polishing compositions further included 0.1% by weight malonic acid, 0.08% by weight ferric nitrate nonahydrate (Fe(NO₃)₃·9H₂O), 0.02% by weight L-lysine, 0.02% aluminum nitrate nonhydrate, 5 ppm by weight Kathon LX preservative, and 2 weight percent hydrogen peroxide. The pH of each composition was adjusted to 2.1 using nitric acid or potassium hydroxide.

Samples of each of the colloidal silica compositions were prepared for TEM imaging (prior to adding the hydrogen peroxide) by drop-casting 30 μL samples onto lacey carbon-coated Cu grids deployed on filters to wick away excess liquid. After drying, multiple TEM bright field images were obtained of the remaining particles (the particles that remain after wicking away of the liquid). In this example, 20 images were obtained for each sample and were stacked into a single file using FIJI open-source image processing software (https://en.wikipedia.org/wiki/Fiji_(software). Each image was obtained at a magnification of 20,000 and included 2048×2048 pixels. Using the FIJI software, the background was subtracted (using a rolling ball process) and the images were contrast enhanced to scale the intensity resolution. The pixel size was computed and input into the software (using the image scale bar). Machine learning software (using the trainable WEKA segmentation algorithm available in FIJI) was used to create binary images of the particle and background (a black particle in a white background). The machine learning software was user guided with the user defining selected particles. The WEKA software then evaluated selected images in the stack. An iterative process enabled the software to accurately find the particles. The learned algorithm was then applied to whole stack to generate binary images. A particle analyzing routine (available in FIJI) was then applied to the images in the stack to compute an aspect ratio for each identified particle in each image (the aspect ratio being defined as the maximum caliper diameter of the particle divided by the minimum caliper diameter of the particle). The median value (AR50) was computed and is recorded in Table 3 for each of the colloidal silica compositions.

The average particle size and the zeta potential of the anionic colloidal silica particles in each of the polishing compositions was measured using a Zetasizer® available from Malvern Instruments prior to adding hydrogen peroxide to the compositions. The BET surface area of each particle was measured as described above using a TriStar II Plus gas adsorption analyzer according to Colloids and Surfaces A: Physicochem. Eng. Aspects 322 (2008) 248-252. The results of the particle characterization measurements are also recorded in Table 3.

TABLE 3

| | | | | Zeta |
|---|---|---|---|---|
| Polishing | TEM AR | DLS Particle | BET SA | Potential |
| Composition | (AR50) | Size (nm) | (m²/g) | (mV) |
| 3A (comparative) | 1.38 | 71 | 91 | −21 |
| 3B (inventive, | 1.19 | 100 | 47 | −24 |
| less preferrable) | | | | |
| 3C (inventive) | 1.11 | 96 | 48 | −27 |

As is readily apparent from the results set forth in Table 3, each of the inventive polishing compositions has an anionic colloidal silica having a zeta potential in a range from about −10 mV to about −40 mV (e.g., from about −10 mV to about −25 mV) in the polishing composition, an aspect ratio of less than about 1.3 (e.g., less than or equal to about 1.2) and a surface area in a range from about 40 m²/g to about 60 m²/e (e.g., from about 40 m²/g to about 60 m²/g). The inventive polishing compositions disclosed in this example also have a particle size in a range from about 50 nm to about 100 nm (e.g., from about 60 nm to about 90 nm).

### Example 4

The blanket wafer and patterned wafer polishing performance of each of the three polishing compositions prepared in Example 3 was evaluated. The wafers were polished using a Mirra® CMP polishing tool (Applied Materials) with an E6088 polishing pad (Entegris) and ex-situ conditioning using a 3M A165 conditioner at 9 lbs for 12 seconds. Tungsten, TEOS, and SiN polishing rates were obtained by polishing 200 mm blanket tungsten, TEOS, and PE-SiN and LP-SiN wafers for 60 seconds at a downforce of 2.5 psi, a platen speed of 113 rpm, a head speed of 111 rpm, and a slurry flow rate was 150 mL/min. Patterned wafers having a 2000 Å tungsten film (MIT 854) were polished at the same conditions until endpoint with a 20 percent overpolish. Blanket wafer polishing rates are shown in Table 4A. Patterned wafer removal rates and oxide loss are shown in Table 4B. Erosion, EoE, and fanging are shown in Table 4C. In Table 4C, the array erosion refers to the average erosion for the array, the Total EoE refers to the total erosion at the edge of the array, and the Local EoE is the excess erosion at the edge of the array (i.e., Total EoE minus Array Erosion).

TABLE 4A

| Polishing | W RR | TEOS RR | LP SiN RR | PE SiN RR |
|---|---|---|---|---|
| Composition | (Å/min) | (Å/min) | (Å/min) | (Å/min) |
| 3A (comparative) | 2595 | 85 | 351 | 517 |
| 3B (inventive, | 1992 | 78 | 228 | 300 |
| less preferred) | | | | |
| 3C (inventive) | 1656 | 55 | 116 | 187 |

TABLE 4B

| Polishing | Pattern W | Pattern Oxide | Pattern Oxide |
|---|---|---|---|
| Composition | RR (Å/min) | RR (Å/min) | Loss (Å) |
| 3A (comparative) | 1899 | 175 | 54 |
| 3B (inventive | 2309 | 244 | 61 |
| less preferred) | | | |
| 3C (inventive) | 1844 | 122 | 41 |

TABLE 4C

| | Fanging | Array Erosion | Local EoE | Total EoE |
|---|---|---|---|---|
| Polishing | 1 × 1 μm | 0.18 × 0.18 μm | (Center, | (Center, |
| Composition | (Center, Å) | (Center, Å) | Å) | Å) |
| 3A (comparative) | 173 | 193 | 10 | 203 |
| 3B (inventive, | 139 | 86 | 0 | 86 |
| less preferred) | | | | |
| 3C (inventive) | 39 | 15 | 0 | 15 |

As is evident from the results set forth Tables 4A-4C, inventive polishing compositions 3B and 3C exhibit significantly improved fanging, erosion, and EoE as compared to the comparative compositions. Moreover, the inventive polishing compositions 3B and 3C exhibit a similar patterned tungsten removal rate as compared to the other compositions.

It will be understood that the recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical mechanical polishing composition comprising:
a liquid carrier;
an iron containing tungsten polishing accelerator;
an inhibitor of tungsten etching;
anionic colloidal silica particles dispersed in the liquid carrier;
wherein the anionic colloidal silica particles have a zeta potential in a range from about −10 mV to about −40 mV in the polishing composition, an aspect ratio of less than about 1.3, and a surface area in a range from about 40 m²/g to about 80 m²/g; and
wherein the composition has a pH of less than about 5.

2. The composition of claim 1, wherein the zeta potential is in a range from about −10 mV to about −30 mV in the polishing composition.

3. The composition of claim 1, wherein the anionic colloidal silica particles have an aspect ratio of less than about 1.2.

4. The composition of claim 1, wherein the anionic colloidal silica particles have a surface area in a range from about 40 m²/g to about 60 m²/g.

5. The composition of claim 1, wherein the anionic colloidal silica particles have a DLS particle size in a range from about 50 nm to about 100 nm.

6. The composition of claim 1, wherein the anionic colloidal silica particles have a DLS particle size in a range from about 60 nm to about 80 nm.

7. The composition of claim 1, wherein the anionic colloidal silica particles have a TEM particle size in a range from about 50 nm to about 80 nm.

8. The composition of claim 1, wherein:
the zeta potential is in a range from about −10 mV to about −30 mV in the polishing composition;
the anionic colloidal silica particles have an aspect ratio of less than about 1.15;
the anionic colloidal silica particles have a surface area in a range from about 40 m²/g to about 60 m²/g; and
the anionic colloidal silica particles have a DLS particle size in a range from about 60 nm to about 90 nm.

9. The composition of claim 1, wherein the anionic colloidal silica particles are surface modified with a negatively charged sulfonic acid containing group.

10. The composition of claim 1, comprising from about 0.5 weight percent to about 5 weight percent of the anionic colloidal silica particles at point of use.

11. The composition of claim 1, wherein the iron-containing accelerator comprises a soluble iron catalyst and a dicarboxylic acid stabilizer bound to the soluble iron catalyst.

12. The composition of claim 1, further comprising a hydrogen peroxide oxidizer.

13. The composition of claim 1, wherein the inhibitor of tungsten etching comprises an amino acid.

14. The composition of claim 1, further comprising a polyamino acid topography control agent.

15. The composition of claim 1, further comprising an anionic polymer or an anionic surfactant.

16. The composition of claim 1, wherein the pH is in a range from about 2 to about 4.

17. A chemical mechanical polishing composition comprising:
a liquid carrier;
a soluble iron catalyst and a dicarboxylic acid stabilizer bound to the soluble iron catalyst;
an amino acid inhibitor of tungsten etching;
anionic colloidal silica particles dispersed in the liquid carrier;
wherein the anionic colloidal silica particles have a zeta potential in a range from about −10 mV to about −30 mV in the polishing composition, an aspect ratio of less than about 1.15, a DLS particle size in a range from about 50 to about 100 nm, and a surface area in a range from about 40 m²/g to about 60 m²/g; and
wherein the composition has a pH in a range from about 2 to about 4.

18. The composition of claim 17, wherein the anionic colloidal silica particles are surface modified with a negatively charged sulfonic acid containing group.

19. The composition of claim 17, comprising from about 0.5 weight percent to about 5 weight percent of the anionic colloidal silica particles.

20. A method of chemical mechanical polishing a substrate having a tungsten layer or a molybdenum layer, the method comprising:
(a) contacting the substrate with the polishing composition of claim 17;
(b) moving the polishing composition relative to the substrate; and
(c) abrading the substrate to remove a portion of the tungsten layer or the molybdenum layer from the substrate and thereby polish the substrate.
